(19) United States
(12) Patent Application Publication
(10) Pub. No.: US 2022/0262779 A1
(43) Pub. Date: Aug. 18, 2022

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazuhiro Inoue, Kitakyushu Fukuoka (JP); Yoshio Noguchi, Kitakyushu Fukuoka (JP); Atsushi Takeshita, Kitakyushu Fukuoka (JP); Toshihide Osanai, Buzen Fukuoka (JP)

(21) Appl. No.: 17/468,609

(22) Filed: Sep. 7, 2021

(30) Foreign Application Priority Data
Feb. 18, 2021 (JP) 2021-023980

(51) Int. Cl. H01L 25/16

(52) U.S. Cl. CPC H01L 25/162; H03K 17/785; H01L 25/167

(57) ABSTRACT

A semiconductor device includes a light-emitting element, a light-receiving element, an input-side terminal, a first switching element, a first lead and a resin package. The first lead includes a first mount bed and a first output-side terminal, the first switching element being mounted on the first mount bed. The resin package seals the light-emitting element, the light-receiving element, and the first switching element. The resin package includes first and second side surfaces opposite to each other. The input-side terminal protrudes from the first side surface. The first output-side terminal protrudes from the second side surface. The first switching element is sealed at a center between the first and second side surfaces. The first mount bed is arranged in a direction along the second side surface so that a side surface of the first mount bed is positioned between a center of the resin package and the first output-side terminal.

### CROSS-REFERENCE TO RELATED APPLICATIONS

This application is based upon and claims the benefit of priority from Japanese Patent Application No. 2021-023980, filed on Feb. 18, 2021; the entire contents of which are incorporated herein by reference.

### FIELD

Embodiments relate to a semiconductor device.

### BACKGROUND

When a semiconductor device is used under high voltage and high current conditions, a semiconductor chip may have the surface area enlarged to increase the current capacity. In such a semiconductor device, the semiconductor chip is sealed in a resin package, and may be broken by internal stress due to the thermal expansion coefficient difference of package materials.

### BRIEF DESCRIPTION OF THE DRAWINGS

FIG. 1 is a perspective view schematically showing a semiconductor device according to an embodiment;

FIGS. 2A and 2B are schematic views showing the semiconductor device according to the embodiment;

FIGS. 3A to 3C are schematic views showing the configuration of the semiconductor device according to the embodiment;

FIGS. 4A to 4C are schematic views showing characteristics of the semiconductor device according to the embodiment;

FIGS. 5A and 5B are schematic views showing a semiconductor device according to a modification of the embodiment.

### DETAILED DESCRIPTION

According to an embodiment, a semiconductor device includes a light-emitting element; an input-side terminal electrically connected to the light-emitting element; a light-receiving element optically combined with the light-emitting element, the light-emitting element and the light-receiving element being arranged in a first direction; a first switching element electrically connected to the light-receiving element, the light-receiving element and the first switching element being arranged in a second direction crossing the first direction; a first lead including a first mount bed and a first output-side terminal, the first switching element being mounted on the first mount bed, the first output-side terminal being electrically connected to the first switching element; and a resin package sealing the light-emitting element, the light-receiving element, the first switching element, and the first mount bed of the first lead. The resin package includes a major surface crossing the first direction, and first to third side surfaces. The first and second side surfaces each extend along the second direction. The third side surface extends along a third direction directed from the first side surface toward the second side surface. The input-side terminal protrudes from the first side surface. The first output-side terminal protrudes from the second side surface. The first switching element is sealed between the first side surface and the second side surface. The first switching element is arranged in the third direction to be positioned at a center between the first side surface and the second side surface. The first lead includes an internal side surface of the first mount bed, and an external side surface of the first output-side terminal. The internal side surface of the first mount bed faces the third side surface. The external side surface of the first output-side terminal crosses the second direction. The first mount bed is arranged in the second direction so that the internal side surface thereof is positioned between a center of the resin package and the external side surface of the first output-side terminal.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

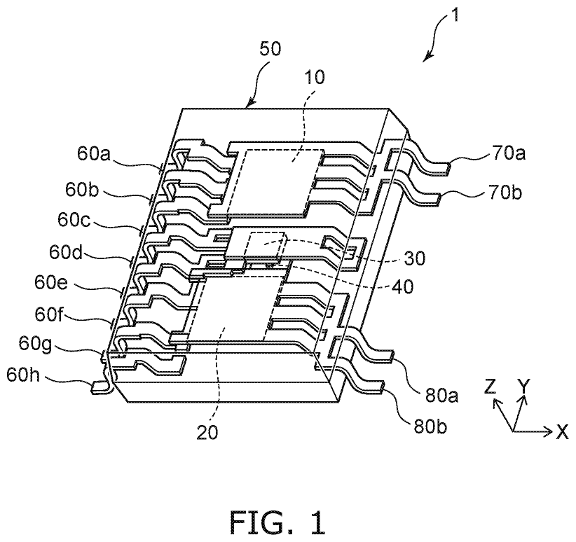

FIG. 1 is a perspective view schematically showing a semiconductor device 1 according to an embodiment. The semiconductor device 1 is, for example, a photorelay that includes a photocoupler.

The semiconductor device 1 includes a first switching element 10, a second switching element 20, a light-receiving element 30, a light-emitting element 40, a resin package 50, input-side terminals 60a to 60h, and output-side terminals 70a, 70b, 80a, and 80b. The first switching element 10 and the second switching element 20 are, for example, MOSFETs (Metal Oxide Semiconductor Field Effect Transistors).

The first switching element 10, the second switching element 20, the light-receiving element 30, and the light-emitting element 40 are sealed inside the resin package 50. The input-side terminals 60a to 60h and the output-side terminals 70a, 70b, 80a, and 80b each protrude from the resin package 50.

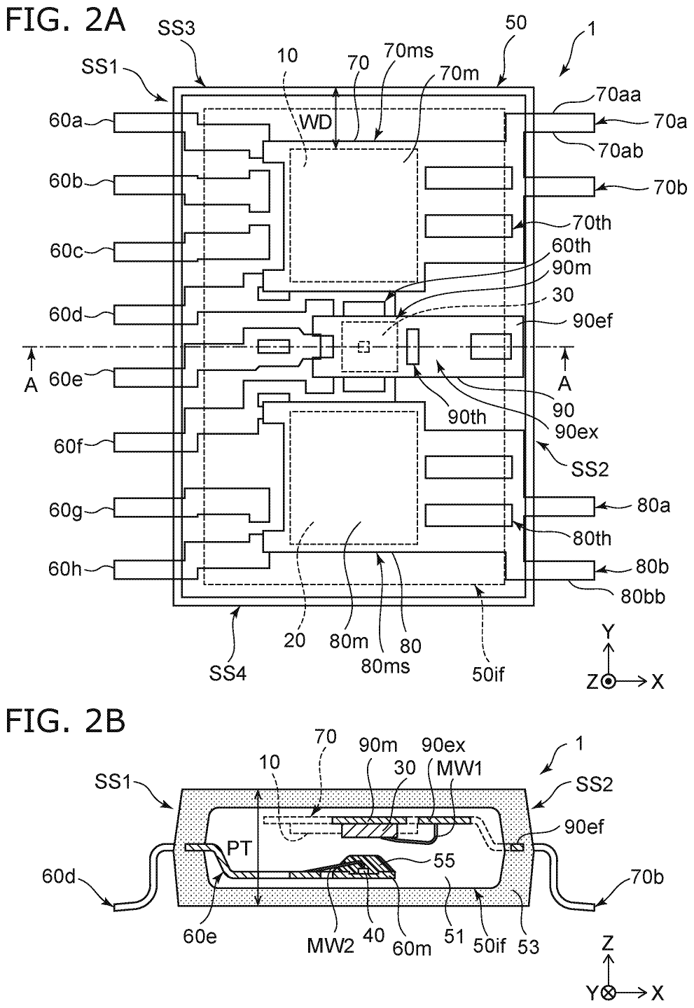

FIGS. 2A and 2B are schematic views showing the semiconductor device 1 according to the embodiment. FIG. 2A is a schematic plan view showing the internal configuration of the resin package 50. FIG. 2B is a cross-sectional view along line A-A shown in FIG. 2A.

As shown in FIG. 2A, the semiconductor device 1 includes a first lead 70, a second lead 80, and a third lead 90. The first lead 70, the second lead 80, and the third lead 90 are, for example, metal plates that include copper or an iron-nickel alloy.

The first lead 70, the second lead 80, and the third lead 90 are sealed inside the resin package 50. The first lead 70A includes portions protruding outside the resin package 50 as the output-side terminals 70a and 70b. The second lead 80A includes portions protruding outside the resin package 50 as the output-side terminals 80a and 80b.

The first lead 70 includes, for example, a mount bed 70m. The first switching element 10 is mounted on the lower surface of the mount bed 70m. The output-side terminals 70a and 70b are electrically connected to the first switching element 10 via the mount bed 70m.

The second lead 80 includes, for example, a mount bed 80m. The second switching element 20 is mounted on the lower surface of the mount bed 80m. The output-side terminals 80a and 80b are electrically connected to the second switching element 20 via the mount bed 80m.

The third lead 90 is provided between the first lead 70 and the second lead 80. The light-receiving element 30 is mounted on the lower surface of the third lead 90.

As shown in FIG. 2A, the input-side terminals 60a to 60h each include a sealed portion that is positioned inside the resin package 50, and a terminal portion that protrudes from the resin package 50.

The resin package 50 includes, for example, a major surface that has a rectangular shape when viewed in top-view; and the major surface includes short sides extending in an X-direction, and long sides extending in a Y-direction. For example, the input-side terminals 60a to 60h and the output-side terminals 70a, 70b, 80a, and 80b protrude from side surfaces of the resin package 50 that are along the long sides.

The resin package 50 includes a first side surface SS1 that is along a long side, a second side surface SS2 at the side opposite to the first side surface SS1, a third side surface SS3 that is along a short side, and a fourth side surface SS4 at the side opposite to the third side surface SS3. The input-side terminals 60a to 60h protrude outside from the first side surface SS1. The output-side terminals 70a, 70b, 80a, and 80b protrude outside from the second side surface SS2.

The output-side terminals 70a and 70b are apart from the output-side terminals 80a and 80b in the Y-direction. The output-side terminal 70a is provided at one end of the second side surface SS2; and the output-side terminal 80b is provided at the other end of the second side surface SS2. The output-side terminal 70b and the output-side terminal 80a are provided with a creepage distance therebetween along the second side surface SS2 that is enough to sustain a prescribed voltage applied between the first lead 70 and the second lead 80. In other words, by increasing the creepage distance between the output-side terminal 70b and the output-side terminal 80a, it is possible to apply a higher voltage between the first lead 70 and the second lead 80 that are sealed in the resin package 50.

As shown in FIG. 2A, the entire third lead 90 is sealed in the resin package 50. By the third lead 90 provided with an end 90ef not exposed at the second side surface SS2, it is possible to prevent the reduction of the breakdown voltage between the output-side terminal 70b and the output-side terminal 80a. That is, the breakdown voltage between the two terminals can be stably ensured by not providing a conductive material exposed between the output-side terminal 70b and the output-side terminal 80a.

The mount bed 70m of the first lead 70 is arranged in the Y-direction to be located between the center of the resin package 50 and the output-side terminal 70a. For example, the output-side terminal 70a includes an external side surface 70aa and an external side surface 70ab. The external side surfaces 70aa and 70ab are provided to cross the Y-direction. The external side surface 70ab faces the output-side terminal 70b; and the external side surface 70aa is positioned at the side opposite to the external side surface 70ab. The mount bed 70m includes an internal side surface 70ms that faces the third side surface SS3 that is along a short side of the resin package 50. The internal side surface 70ms of the mount bed 70m is provided in Y-direction to be located the between the center of the resin package 50 and the external side surface 70aa of the output-side terminal 70a. The mount bed 70m is arranged in the X-direction to be positioned at the center between the first side surface SS1 and the second side surface SS2 of the resin package 50. Thus, the first lead 70 is sealed at a position such that the first switching element 10 is shifted toward the center of the resin package 50.

For example, it is preferable for the first switching element 10 to be sealed in the resin package 50 while being arranged in the X-direction at the center between the first side surface SS1 and the second side surface SS2. Moreover, a spacing WD between the first switching element 10 and the third side surface SS3 of the resin package 50 is greater than ½ of a thickness PT in a Z-direction of the resin package 50.

The mount bed 80m of the second lead 80 also is provided at a position that is shifted toward the center of the resin package 50. The mount bed 80m includes an internal side surface 80ms that faces the fourth side surface SS4 that is along a short side of the resin package 50. The output side terminals 80a and 80b are arranged in the Y-direction. The output-side terminal 80b includes an external side surface facing the output-side terminal 80a and an external side surface 80bb at the side opposite to the output-side terminal 80a. The internal side surface 80ms of the mount bed 80m is provided to be positioned in the Y-direction between the center of the resin package 50 and the external side surface 80bb of the output-side terminal 80b. The mount bed 80m is arranged in the X-direction to be positioned at the center between the first side surface SS1 and the second side surface SS2 of the resin package 50. In other words, the second switching element 20 is sealed at a position that is shifted toward the center of the resin package 50.

As shown in FIG. 2B, the light-receiving element 30 is mounted on the lower surface of the third lead 90. The third lead 90 includes a mount bed 90m and an extension portion 90ex. The light-receiving element 30 is mounted on the lower surface of the mount bed 90m. The extension portion 90ex extends, for example, in the X-direction from the mount bed 90m. The third lead 90 includes an opening 90th between the mount bed 90m and the extension portion 90ex. The opening 90th is provided to improve the adhesion between the resin package 50 and the third lead 90.

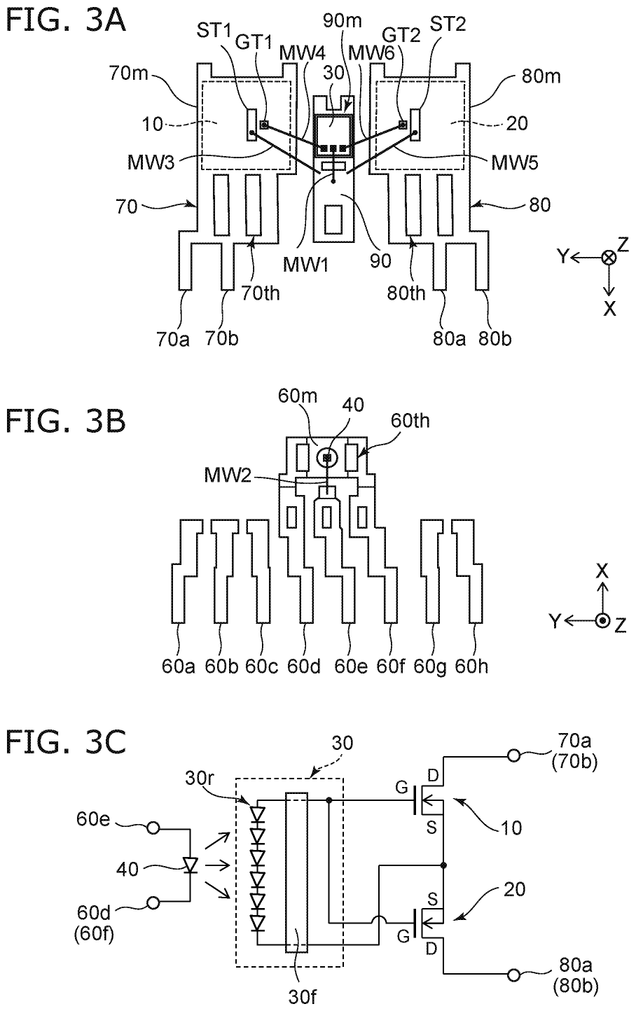

The light-emitting element 40 is mounted on a mount bed 60m. The mount bed 60m, for example, faces the mount bed 90m of the third lead 90 and is connected to the input-side terminals 60d and 60f (referring to FIG. 3B). The light-receiving element 30 and the light-emitting element 40 are arranged to face each other between the mount bed 60m and the third lead 90. The light-receiving element 30 and the light-emitting element 40 are arranged so that the light radiated from the light-emitting element 40 is detected by the light-receiving element 30. That is, the light-receiving element 30 and the light-emitting element 40 are optically combined.

The light-receiving element 30 is electrically connected to the third lead 90, for example, via a metal wire MW1. The light-emitting element 40 has a back side electrically connected to at least one of the input-side terminal 60d or the input-side terminal 60f via the mount bed 60m. The light-emitting element 40 has a front side electrically connected to the input-side terminal 60e via a metal wire MW2.

The resin package 50 includes a first resin 51, a second resin 53, and a third resin 55. The first resin 51 seals the first switching element 10, the second switching element 20, and the light-receiving element 30 inside the first resin 51. The second resin 53 is molded to cover the first resin 51. The second resin 53 also seals the third lead 90. The third resin 55 seals the light-emitting element 40 on the mount bed 60m. The first resin 51 is molded to cover the third resin 55.

The first resin 51 and the second resin 53 are, for example, epoxy resins. The third resin 55 is, for example, a silicone resin. The first resin 51 and the third resin 55 transmit the light of the light-emitting element 40. The second resin 53 includes a material that shields the light of the light-emitting element 40, e.g., an oxide particle, a nitride particle, a carbide particle, a conjugated compound particle, or carbon, etc. For example, it is preferable for the second resin 53 to have the thermal expansion coefficient greater than the thermal expansion coefficient of the first resin 51 so that the first resin 51 is compression-sealed.

The first lead 70 and the second lead 80 protrude externally from the first resin 51 via the second resin 53. The third lead 90 extends from the first resin 51 in the second resin 53 but does not protrude externally from the second resin 53. The third lead 90 is cut after the first resin 51 is molded; and the second resin 53 is molded to cover the end 90ef of the third lead 90.

FIGS. 3A to 3C are schematic views showing the configuration of the semiconductor device 1 according to the embodiment. FIG. 3A is a schematic plan view showing the first lead 70, the second lead 80, and the third lead 90. FIG. 3B is a schematic plan view showing the input-side terminals 60a to 60h. FIG. 3C is a circuit diagram.

As shown in FIG. 3A, the first switching element 10 is mounted on the lower surface of the mount bed 70m of the first lead 70. The second switching element 20 is mounted on the lower surface of the mount bed 80m of the second lead 80. The light-receiving element 30 is mounted on the lower surface of the mount bed 90m of the third lead 90.

The first switching element 10 includes a source terminal ST1 and a gate terminal GT1. The source terminal ST1 is electrically connected to the third lead 90, for example, via a metal wire MW3. The gate terminal GT1 is electrically connected to the light-receiving element 30, for example, via a metal wire MW4.

The second switching element 20 includes a source terminal ST2 and a gate terminal GT2. The source terminal ST2 is electrically connected to the third lead 90, for example, via a metal wire MW5. The gate terminal GT2 is electrically connected to the light-receiving element 30, for example, via a metal wire MW6.

The light-receiving element 30 is electrically connected to the third lead 90, for example, via the metal wire MW1. The back surface of the light-receiving element 30 may be electrically connected to the third lead 90 or may be electrically insulated from the third lead 90. When the back surface of the light-receiving element 30 is electrically connected to the third lead 90, the metal wire MW1 can be omitted.

As shown in FIG. 3B, the input-side terminals 60d and 60f each are connected to the mount bed 60m. The light-emitting element 40 is mounted on the mount bed 60m. The light-emitting element 40 is electrically connected to the input-side terminals 60d and 60f via the mount bed 60m. Openings 60th are provided between the mount bed 60m and the input-side terminals 60d and 60f. The light-emitting element 40 is electrically connected to the input-side terminal 60e via the metal wire MW2.

The input-side terminals 60a to 60c, 60g, and 60f are not connected to other components. The input-side terminals 60a to 60c, 60g, and 60f are provided to ensure, for example, the stability and strength when mounting the semiconductor device 1 to a circuit board, etc.

As shown in FIG. 3C, the input-side terminal 60e is connected to the anode side of the light-emitting element 40. The input-side terminal 60d (60f) is connected to the cathode side of the light-emitting element 40. The light-emitting element 40 is, for example, a light-emitting diode (LED).

The light-receiving element 30 includes, for example, multiple photodiodes 30r and a control circuit 30f. The photodiodes 30r are connected in series and are electrically connected to the control circuit 30f. The control circuit 30f is, for example, a waveform shaping circuit.

The first switching element 10 and the second switching element 20 are, for example, MOSFETs. The drain of the first switching element 10 is electrically connected to the output-side terminal 70a (70b). The drain of the second switching element 20 is electrically connected to the output-side terminal 80a (80b). The source of the first switching element 10 and the source of the second switching element are electrically connected via the third lead 90.

The anode-side output of the light-receiving element 30 is electrically connected to the gate of the first switching element 10 and the gate of the second switching element. On the other hand, the cathode-side output of the light-receiving element 30 is electrically connected to the source of the first switching element and the source of the second switching element via the third lead 90.

For example, the light-emitting element 40 is driven by the current (the input signal) that flows between the input-side terminal 60e and the input-side terminal 60d, and radiates a signal light that corresponds to the input signal. The light-receiving element 30 detects the signal light of the light-emitting element 40. The light-receiving element 30 outputs an voltage that corresponds to the input signal, and applies the output voltage between the gate and source of the first switching element 10 and between the gate and source of the second switching element 20. Thereby, the on-off control of the electric conduction can be performed between the output-side terminal 70a and the output-side terminal 80b.

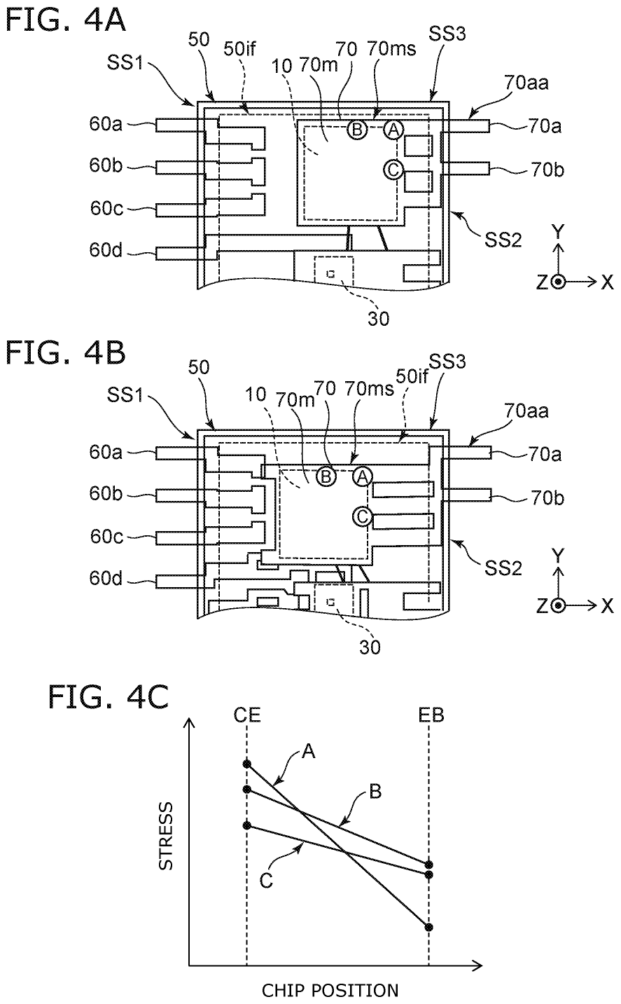

FIGS. 4A to 4C are schematic views showing characteristics of the semiconductor device 1 according to the embodiment. FIG. 4A is a schematic plan view illustrating a semiconductor device according to a comparative example. FIG. 4B is a schematic plan view illustrating the semiconductor device 1.

FIGS. 4A and 4B are partial plan views illustrating locations of the mount bed 70m of the first lead 70. FIG. 4C is a graph showing the stress applied to the first switching element 10.

As shown in FIG. 4A, in the semiconductor device according to the comparative example, the mount bed 70m is provided at the vicinity of an interface 50if between the first resin 51 and the second resin 53. For example, the side surface 70ms of the mount bed 70m that faces the side surface of the resin package 50 along the short side is arranged in the Y-direction to be at the same position as a position of the side surface 70aa of the output-side terminal 70a. In other words, when viewed in top-view, the side surface of the mount bed 70m and the side surface 70aa of the output-side terminal 70a are continuously linked without a step between the side surface of the mount bed 70m and the side surface 70aa of the output-side terminal 70a.

As shown in FIG. 4B, in the semiconductor device 1, the mount bed 70m is provided at a position that is apart from the interface 50if of the first resin 51 and the second resin 53. In other words, it is preferable for the mount bed 70m to be provided at a position that is more distal to the side surface of the resin package 50 along the short side and the side surface of the resin package 50 along the long side.

The mount bed 70m, for example, is arranged in the X-direction to be positioned at the center between the first side surface SS1 and the second side surface SS2 of the resin package 50. The first switching element 10 that is mounted on the mount bed 70m also is arranged in the X-direction to be positioned at the center between the first side surface SS1 and the second side surface SS2 of the resin package 50. The side surface 70ms of the mount bed 70m is arranged in the Y-direction to be positioned between the center of the resin package 50 and the side surface 70aa of the output-side terminal 70a.

FIG. 4C illustrates the stress that is applied to the first switching element 10 mounted on the mount bed 70m. The mount bed 70m is provided in one half of the package 50. The horizontal axis is the chip position along a direction toward the center of the one half of the package 50 from the corner at which the second side surface SS2 and the third side surface SS3 contact; and the vertical axis is the stress strength. In the figure, “CE” illustrates the position of the first switching element 10 of the semiconductor device according to the comparative example. “EB” illustrates the position of the first switching element 10 of the semiconductor device 1.

In FIG. 4C, the stress applied to the first switching element 10 is shown at positions A, B, and C in FIGS. 4A and 4B. The “stress” shown in FIG. 4 is caused by the thermal expansion coefficient differences between the materials of components, i.e., the first resin 51, the second resin 53, and the first lead 70.

The position A corresponds to the corner of the first switching element 10. The position B is the center of the side surface of the first switching element 10 that faces the third side surface SS3 of the resin package 50. The position C is the center of the side surface of the first switching element 10 that faces the second side surface SS2 of the resin package 50.

As shown in FIG. 4C, the stress that is applied to the first switching element 10 of the semiconductor device 1 is less than the stress that is applied to the first switching element 10 of the semiconductor device according to the comparative example. In particular, it can be seen that the stress applied to the first switching element 10 is greatly reduced at the position A. That is, in the embodiment, the stress is significantly reduced at the corner in which a chip crack may occur easily.

Thus, by sealing the first switching element 10 at a position that is more distal to the first, second, and third side surfaces SS1, SS2, and SS3 of the resin package 50, the stress applied to the first switching element 10 due to the temperature change can be reduced, and the element breakdown can be prevented.

In other words, the stress applied to the first switching element 10 can be reduced by providing the first switching element 10 to be distant to the end of the resin package 50 at which stress concentration may easily occurs. Also, because the mount bed 70m of the first lead 70 is provided at the center between the first side surface SS1 and the second side surface SS2, the first lead 70 is proximate to the input-side terminals 60a to 60d in top-view. Thereby, in the top-view of the resin package 50, an area that includes the first resin 51 and the second resin 53 without other components becomes narrow, which may increase the rigidity of the package 50 with respect to the deformation in the Z-direction such as flexion and like. Thus, the stress that is applied to the first switching element 10 also can be reduced.

The first lead 70 includes multiple openings 70th that are provided between the mount bed 70m and the second side surface SS2 of the resin package 50 (referring to FIG. 2A). The second lead 80 includes multiple openings 80th that are provided between the second side surface SS2 and the mount bed 80m (referring to FIG. 2A). In the top-view from the Z-direction, the input-side terminals 60a and 60d include portions overlapping the mount bed 70m. Also, the input-side terminals 60f and 60h include portions overlapping the mount bed 80m. In such a configuration, the stress may be applied isotropically to the first and second switching elements 10 and 20, which prevents the element breakdown. It may be noted that there is a case in which at least one of the input-side terminals 60a to 60d overlaps the mount bed 70m in top-view, and at least one of the input-side terminals 60f to 60h overlaps the mount bed 80m in top-view.

The first switching element 10 is sealed, for example, at the center in the top view of the one half of the resin package 50 in the Y-direction. Similarly, the second switching element 20 is sealed at a position that is more distal to the first, second, and fourth side surfaces SS1, SS2, and SS4 of the resin package 50 (referring to FIG. 2A). The second switching element 20 may be sealed, for example, at the center in the top view of another half of the resin package 50 in the Y-direction.

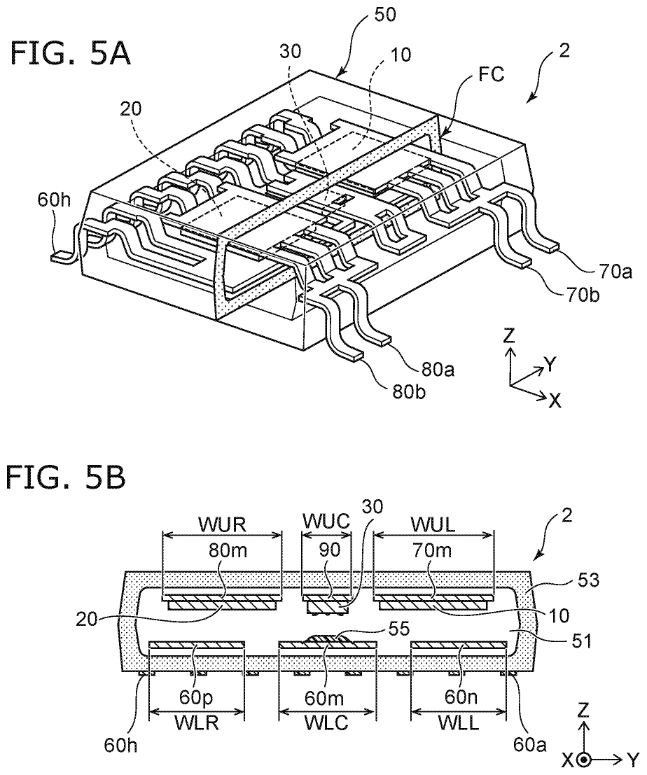

FIGS. 5A and 5B are schematic views showing a semiconductor device 2 according to a modification of the embodiment. FIG. 5A is a perspective view showing the semiconductor device 2. FIG. 5B is a cross-sectional view along FC shown in FIG. 5A. FC is a cross section parallel to the Y-Z plane.

As shown in FIG. 5A, the semiconductor device 2 also includes the first switching element 10, the second switching element 20, the light-receiving element 30, and the light-emitting element 40 (not illustrated) that are sealed inside the resin package 50. The first switching element 10 is mounted on the lower surface of the mount bed 70m of the first lead 70; and the second switching element 20 is mounted on the lower surface of the mount bed 80m of the second lead 80. The light-receiving element 30 is mounted on the lower surface of the mount bed 90m of the third lead 90. The light-emitting element 40 is mounted on the mount bed 60m. The light-emitting element 40 is arranged so that the light-emitting element 40 and the light-receiving element 30 face each other.

As shown in FIG. 5B, the semiconductor device 2 further includes metal plates 60n and 60p. The metal plate 60n is provided, for example, at a position that faces the mount bed 70m, and is connected to the input-side terminals 60a to 60c (referring to FIG. 3B). The metal plate 60p is provided, for example, at a position that faces the mount bed 80m, and is connected to the input-side terminals 60g and 60h (referring to FIG. 3B).

By providing the metal plates 60n and 60p, the stress due to the expansion and contraction of the first, second, and third leads 70, 80, and 90 may be cancelled, or may be uniformly dispersed in the X-direction, the Y-direction, and the Z-direction. For example, the sum of WUL, WUR, and WUC is substantially equal to the sum of WLL, WLR, and WLC, wherein the widths in the Y-direction of the first, second, and third leads 70, 80, and 90 are respectively WUL, WUR, and WUC, and the widths in the Y-direction of the metal plates 60n and 60p and the mount bed 60m are respectively WLL, WLR, and WLC.

The mount bed 70m covers a space between the mount bed 60m and the metal plate 60n when viewed in top-view. The mount bed 80m also covers a space between the mount bed 60m and the metal plate 60p when viewed in top-view. Moreover, the mount bed 60m includes a portion that is positioned in a space between the first lead 70 and the third lead 90 when viewed in top-view. The mount bed 60m also includes another portion that is positioned in a space between the second lead 80 and the third lead 90 when viewed in top-view. The flexion of the resin package 50 in the Z-direction can be suppressed thereby, and the stress that is applied to the first and second switching elements 10 and 20 can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a light-emitting element;
an input-side terminal electrically connected to the light-emitting element;
a light-receiving element optically combined with the light-emitting element, the light-emitting element and the light-receiving element being arranged in a first direction;
a first switching element electrically connected to the light-receiving element, the light-receiving element and the first switching element being arranged in a second direction crossing the first direction;
a first lead including a first mount bed and a first output-side terminal, the first switching element being mounted on the first mount bed, the first output-side terminal being electrically connected to the first switching element; and
a resin package sealing the light-emitting element, the light-receiving element, the first switching element, and the first mount bed of the first lead,
the resin package including a major surface crossing the first direction, and first to third side surfaces, the first and second side surfaces each extending along the second direction, the third side surface extending along a third direction directed from the first side surface toward the second side surface, the input-side terminal protruding from the first side surface, the first output-side terminal protruding from the second side surface,
the first switching element being sealed between the first side surface and the second side surface, the first switching element being arranged in the third direction to be positioned at a center between the first side surface and the second side surface,
the first lead including an internal side surface of the first mount bed, and an external side surface of the first output-side terminal, the internal side surface of the first mount bed facing the third side surface, the external side surface of the first output-side terminal crossing the second direction,
the first mount bed being arranged in the second direction so that the internal side surface of the first mount bed is positioned between a center of the resin package and the external side surface of the first output-side terminal.

2. The device according to claim 1, wherein
a spacing between the first switching element and the third side surface of the resin package is greater than ½ of a thickness in the first direction of the resin package.

3. The device according to claim 1, wherein
a spacing between the first switching element and the first side surface of the resin package is equal to a spacing between the first switching element and the second side surface of the resin package.

4. The device according to claim 1, further comprising:
a second switching element electrically connected to the light-receiving element;
a second lead including a second mount bed and a second output-side terminal, the second switching element being mounted on the second mount bed, the second switching element and the second mount bed being sealed in the resin package, the second output-side terminal protruding from the second side surface of the resin package, the second switching element being electrically connected to the second output-side terminal; and
a third lead sealed in the resin package, the light-receiving element being mounted on the third lead,
the first lead, the second lead, and the third lead being arranged in the second direction, the third lead being provided between the first lead and the second lead,
the resin package including a fourth side surface opposite to the third side surface,
the second lead including a second internal side surface of the second mount bed, and a second external side surface of the second output-side terminal, the second internal side surface of the second mount bed facing the fourth side surface of the resin package, the second external side surface of the second output-side terminal crossing the second direction,
the second switching element being arranged in the third direction to be positioned at the center between the first side surface and the second side surface of the resin package,
the second mount bed being arranged in the second direction so that the second internal side surface of the second mount bed is positioned between the center of the resin package and the second external side surface of the second output-side terminal.

5. The device according to claim 4, wherein
the third lead is sealed entirely inside the resin package.

6. The device according to claim 4, wherein
the resin package includes a first resin member and a second resin member,
the second resin member covers the first resin member, and
the light-emitting element, the light-receiving element, the first switching element, and the second switching element are sealed inside the first resin member.

7. The device according to claim 6, wherein
the first resin member extends between the light-emitting element and the light-receiving element and transmits light radiated from the light-emitting element.

8. The device according to claim 7, wherein
the second resin member includes a material shielding the light radiated from the light-emitting element.

9. The device according to claim 6, wherein
the third lead includes a main portion and an end portion, the main portion being sealed inside the first resin member, the end portion protruding from the first resin member, the end portion being covered with the second resin member.

10. The device according to claim 4, further comprising:
a third mount bed electrically connected to the input-side terminal, the light-emitting element being mounted on the third mount bed, the light-emitting element and the third mount bed being sealed in the resin package, the third mount bed facing the third lead in the first direction,
the light-emitting element and the light-receiving element being arranged to face each other between the third mount bed and the third lead.

11. The device according to claim 10, wherein
a plurality of the input-side terminals are provided, the plurality of input-side terminals including first and second input terminals,
the first input terminal being electrically connected to the light-emitting element via the third mount bed at a back side of the light-emitting element,
the second input terminal being electrically connected to the light-emitting element via a metal wire at a front side of the light-emitting element.

12. The device according to claim 10, further comprising:
a first metal plate facing the first mount bed of the first lead, the first metal plate and the first mount bed being arranged in the first direction; and
a second metal plate facing the second mount bed of the second lead, the second metal plate and the second mount bed being arranged in the first direction,
the first and second metal plates being sealed in the resin package, the first metal plate, the second metal plate, and the third mount bed being arranged in the second direction, the third mount bed being provided between the first metal plate and the second metal plate.

13. The device according to claim 12, wherein
a sum of widths in the second direction of the first mount bed of the first lead, the second mount bed of the second lead, and the third lead are substantially equal to a sum of widths in the second direction of the first metal plate, the second metal plate, and the third mount bed.

14. The device according to claim 12, wherein
the third mount bed includes a portion positioned in a space between the first lead and the third lead in a planar view perpendicular to the first direction; and a portion positioned in a space between the second lead and the third lead in the planar view perpendicular to the first direction.
